(19) United States
(12) Patent Application Publication
(10) Pub. No.: US 2005/0041473 A1
(43) Pub. Date: Feb. 24, 2005

(54) Non-volatile memory storage integrated circuit

(75) Inventors: Khein-Seng Pua, Hsinchu Hsien (TW); Chee-Kong Awyong, Hsinchu Hsien (TW)

Correspondence Address: BACON & THOMAS, PLLC, 625 SLATERS LANE, FOURTH FLOOR, ALEXANDRIA, VA, 22314, US

(73) Assignee: Phison Electronics Corp., Hsinchu Hsien (TW)

(21) Appl. No.: 10/634,963

(22) Filed: Aug. 6, 2003

(51) Int. Cl. G11C 16/04

(52) U.S. Cl. 365/185.17; 710/104

(57) ABSTRACT

A non-volatile memory storage integrated circuit is disclosed. The non-volatile memory storage integrated circuit of the present invention comprises a controlling IC, a NAND IC and a memory IC. The non-volatile memory storage integrated circuit of the present invention can be used as a basic I/O system for electronic devices.

### BACKGROUND OF THE INVENTION

1. The Field of the Invention

The present invention provides a non-volatile memory storage integrate circuit, and particularly a non-volatile memory storage integrate circuit comprising a USB interface terminal, a controlling IC, a NAND flash memory IC, a memory IC, an I/O control interface terminal, memory card interface terminal and a memory interface terminal.

2. Description of the Related Art

Nowadays the USB interface is the standard interface of the PC/NB/IA products, and these products are bootable by using the storage media with the USB interface and the capacity of the hard disk is accordingly increased. However, the inconvenience is existed for the available storage media with the serial transmission interface are mostly external peripheral devices.

The available miniaturized IA products, such as PDA, industrial computer, digital camera and the like, require additional operating systems, for example, Win CE/Linux, for the multi-functional design. A CPU and a NOR type flash memory are required for storing the booting program of these operation system. And if any data storage space is required, then additional SRAM or built-in NAND flash memory are needed for meeting such requirements. However, the above objectives are not in compliance with the standard Win CE/Linux interface, and therefore, the designers need to alter the driver program or appliance program for this operation system, and an additional memory card with retrieving and storing interface IC functionalities is required for retrieving and storing memory. Therefore, the expense on researching and developing modified or new driver program or appliance program for every new product is very high.

### SUMMARY OF THE INVENTION

Accordingly, in the view of the foregoing, the present inventor makes a detailed study of related art to evaluate and consider, and uses years of accumulated experience in this field, and through several experiments, to create a new a non-volatile memory storage integrate circuit that can be used as basic I/O system (BIOS). Accordingly, modification of the driver program or appliance program for every new product can be effectively avoided.

According to one aspect of the present invention, a controlling IC (including the solder balls thereof), a NAND IC (including the solder balls thereof) and a memory IC (including the solder balls thereof) are integrated into a single non-volatile memory storage integrated circuit and packaged into a single package, accordingly the connector of the package comprises:
at least a USB transmission interface terminal of the controlling IC for connecting with the electronic device;
at least a I/O control interface terminal of the controlling IC for connecting with the electronic device;
at least a memory card IC interface terminal (such as SD/MMC, SM, MS, CF/ATAPI) of the controlling IC for connecting with memory card (such as CF card and SM card); and
at least a memory interface terminal (SRAM terminal/NOR IC terminal) for connecting with memory externally for increasing the capacity and used as the basic I/O system (BIOS).

The non-volatile memory storage integrated circuit of the present invention can also be designed to integrate a USB transmission interface connector terminal for building the non-volatile memory storage integrate circuit into a PDA, industrial computer, digital camera and so on. The non-volatile storage integrated circuit can be applied as a bootable silicon chip, storage for the program code and data, and the function thereof will be just like a hard disk of a computer.

### BRIEF DESCRIPTION OF THE DRAWING

For a more complete understanding of the present invention, reference will now be made to the following detailed description of preferred embodiments taken in conjunction with the accompanying drawings, in which:

FIG. 1 is a block diagram of the non-volatile memory storage integrated circuit according to a preferred embodiment of the present invention;

FIG. 2 is a block diagram of the non-volatile memory storage integrated circuit according to another preferred embodiment of the present invention; and

FIG. 3 is a block diagram of the non-volatile memory storage integrated circuit according to another preferred embodiment of the present invention.

### DETAILED DESCRIPTION OF PREFERRED EMBODIMENTS

Reference will be made in detail to the preferred embodiments of the invention, examples of which are illustrated in the accompanying drawings. Wherever possible, the same reference numbers are used in the drawings and the description to refer to the same or like parts.

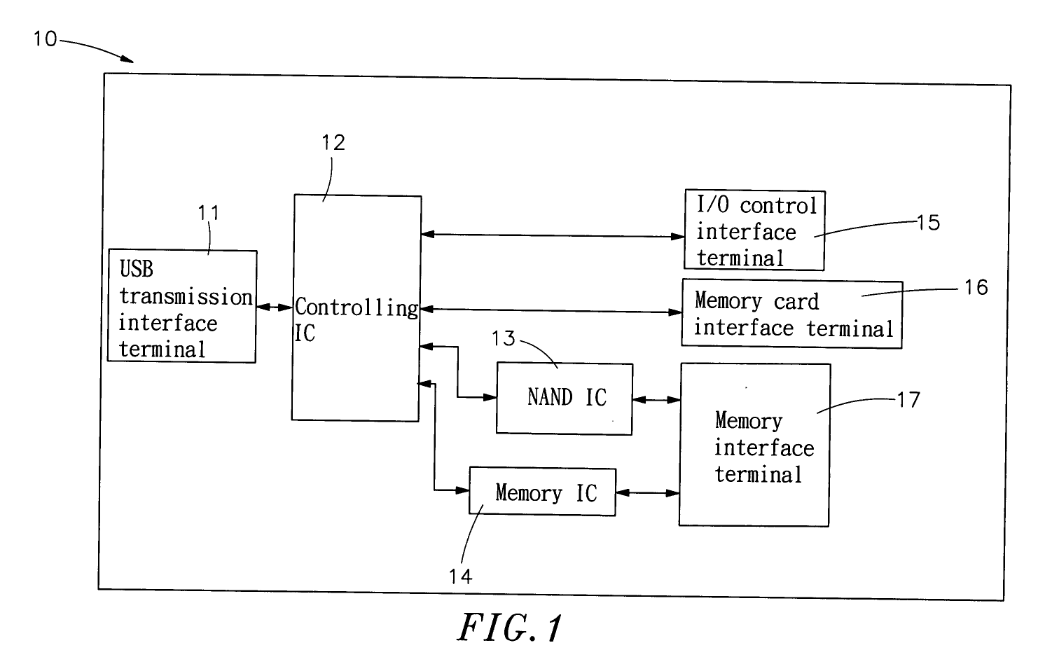

Referring to FIG. 1, shows a block diagram of the non-volatile memory storage integrated circuit according to preferred embodiment of the present invention. The package of the non-volatile memory storage integrated circuit 10 comprises a USB transmission interface terminal 11, a controlling IC 12, a NAND IC 13, a memory IC 14, I/O control interface terminal 15, a memory card interface terminal 16 and a memory interface terminal 17. Wherein the controlling IC 12 has a built-in ECC and calculation means. The controlling IC 12 is for retrieving and storing data into the flash memory cell. The memory IC 14 comprises a booting program code for installing the non-volatile memory storage integrated circuit 10 in the circuit of an electronic device, for example, a PDA, an industrial computer, a digital camera and the like. While booting the computer, the controller of the electronic device retrieves the booting program code from the memory IC 14 of the non-volatile memory storage integrated circuit 10. The memory IC 14 can be used as the basic I/O system of the electronic device. An electronic device can connect and communicate with the non-volatile memory storage integrated circuit 10 through the USB transmission interface terminal 11 and the I/O control interface terminal 15 without the need of installing any driver program. Additionally, the capacity of the memory interface terminal 17 of the non-volatile memory storage integrated circuit 10 can be extendable by merely connecting the terminal corresponding to the memory interface terminal 17 to the desired memory terminal. Further, the memory IC 14 can also extend the capacity of the non-volatile memory storage integrated circuit 10. Besides, the electronic device can also use the memory card interface terminal 16 of the non-volatile memory storage integrated circuit 10 to connect and communicate with the memory card, such as CF card and SM card).

FIG. 1 also shows the non-volatile memory storage integrated circuit 10 may be packaged into a Chip Scale Package (CSP) and Ball Grid Array (BGA).

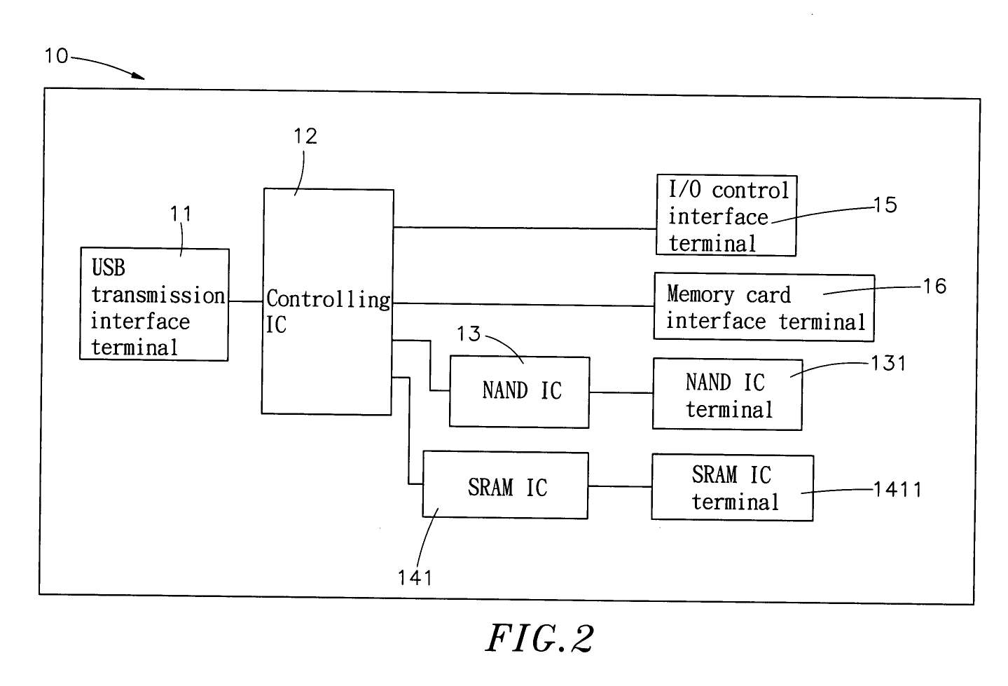

Referring to FIG. 2, the memory IC 14 of the non-volatile memory storage integrated circuit 10 (as shown in FIG. 1) may be a SRAM IC 141. The NAND IC 13 has a booting program code to for installing the non-volatile memory storage integrated circuit 10 in the circuit of an electronic device, for example, a PDA, an industrial computer, a digital camera and the like. While booting the device, the controller IC 12 of the non-volatile memory storage integrated circuit 10 retrieves the booting program code from the NAND IC 13 then writes it into the SRAM IC 141. The SRAM IC 141 can be used as the basic I/O system of the electronic device. Further, the NAND IC 13 and the SRAM IC 141 of the non-volatile memory storage integrated circuit 10 are individually connected with the NAND IC terminal 131 and SRAM IC terminal 1411 to easily extend the capacity of the non-volatile memory storage integrated circuit 10, by merely connecting the terminal corresponding to the SRAM IC terminal 1411 to the desired memory terminal. Furthermore, by using the memory IC the capacity of the non-volatile memory storage integrated circuit 10 can be further extended.

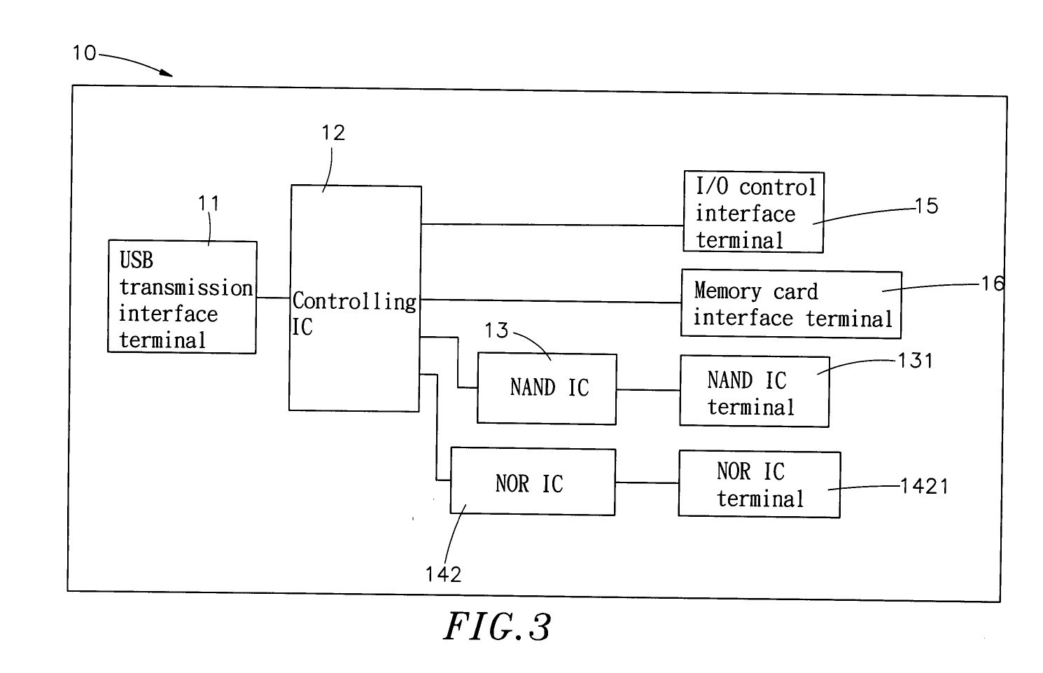

Referring to FIG. 3, the memory IC 14 of the non-volatile memory storage integrated circuit 10 (as shown in FIG. 1) may be a NOR IC 142. The NOR IC 142 has a booting program code for installing the non-volatile memory storage integrated circuit 10 in the circuit of an electronic device, for example, a PDA, an industrial computer, a digital camera and the like. While booting the device, the controller of the electronic device retrieves the booting program code from the NOR IC 142. The NOR IC 142 can be used as the basic I/O system of the electronic device. The NAND IC 13 and the NOR IC 142 of the non-volatile memory storage integrated circuit 10 are individually connecting to the NAND IC terminal 131 and NOR IC terminal 1421 to easily extend the capacity of the non-volatile memory storage integrated circuit 10, merely by connecting the terminal corresponding to the NOR IC terminal 1421 to the desired memory terminal. Further by using the memory IC the capacity of the non-volatile memory storage integrated circuit 10 can be further extended.

Therefore, the embodiments of the present invention can directly support the storage media with the USB transmission interface without any extra driver program, and the need for researching and developing driver or appliance program can be effectively avoided and thereby the cost on research and development for this purpose can be effectively eliminated. The controller IC 12 supports In-System-Programming, and the program code of the USB controller can be changed directly through the USB transmission interface terminal 11.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

1. A non-volatile memory storage integrated circuit comprising a controller IC, a NAND IC and a memory IC, wherein said controller IC has a USB transmission interface terminal.

2. The non-volatile memory storage integrated circuit according to claim 1, wherein said controller IC comprises an I/O controller interface terminal.

3. The non-volatile memory storage integrated circuit according to claim 1, wherein said controller IC comprises a memory card interface terminal.

4. The non-volatile memory storage integrated circuit according to claim 2, wherein said controller IC comprises a memory interface terminal and an I/O controller interface terminal.

5. The non-volatile memory storage integrated circuit according to claim 3, wherein said controller IC comprises a USB transmission interface terminal and a memory interface terminal.

6. The non-volatile memory storage integrated circuit according to claim 1, wherein said controller IC comprises an I/O controller interface terminal and a memory card interface terminal.

7. The non-volatile memory storage integrated circuit according to claim 6, said controller IC comprises a memory card interface terminal, a USB transmission interface terminal and a memory interface terminal.

8. The non-volatile memory storage integrated circuit according to claim 1, wherein said controller IC comprises a built-in ECC and calculation means.

9. The non-volatile memory storage integrated circuit according to claim 1, wherein said memory IC is a NOR IC or a SRAM IC.

10. The non-volatile memory storage integrated circuit according to claim 1, wherein said non-volatile memory storage integrated circuit is packaged into a Chip Size Package (CSP).

11. The non-volatilized memory storage integrated circuit according to claim 1, wherein said non-volatile memory storage integrated circuit is packaged into a Ball Grid Array (BGA).
